(19) United States
(12) Patent Application Publication
(10) Pub. No.: US 2024/0373599 A1
(43) Pub. Date: Nov. 7, 2024

(54) HOUSING AND HOUSING GRASPING FEATURES USABLE WITH A HEAT DISSIPATING DEVICE

(71) Applicant: Power Integrations, Inc., San Jose, CA (US)

(72) Inventors: DAVID MICHAEL HUGH MATTHEWS, Los Gatos, CA (US); William M. POLIVKA, Campbell, CA (US); Michael MADSON, San Jose, CA (US)

(73) Assignee: Power Integrations, Inc., San Jose, CA (US)

(21) Appl. No.: 18/606,753

(22) Filed: Mar. 15, 2024

Related U.S. Application Data
(60) Provisional application No. 63/500,238, filed on May 4, 2023.

(51) Int. Cl. H05K 7/20; H01R 13/66; H01R 103/00

(52) U.S. Cl. CPC H05K 7/209; H01R 13/6675; H01R 2103/00

(57) ABSTRACT

A housing or surface of a housing containing at least one heat dissipating device configured to be grasped or otherwise held by a user. The housing includes a first housing wall portion with a plurality of grasping features that protrude from the first housing wall portion and a second housing wall portion with a second plurality of grasping features that protrude from the second housing wall portion. The first plurality of grasping features and second plurality of grasping features prevent a user from contacting the first housing wall portion and the second housing wall portion.

### CROSS-REFERENCE TO RELATED APPLICATIONS

This application claims the benefit of U.S. Provisional Application No. 63/500,238, filed May 4, 2023. U.S. Provisional Application No. 63/500,238 is incorporated by reference in its entirety.

### INTRODUCTION

The present disclosure generally relates to a housing or a surface of a housing, particularly to a housing containing a heat dissipating device.

### BACKGROUND

Improvements in electronic technology allow electronic devices to decrease in size with either increased or unchanged capability. These trends pose challenges in the management of heat produced by electronic devices. For example, the evolution of battery technology that allows batteries to acquire more charge in less time leads to a demand for chargers that deliver greater power in a smaller volume. The desire to decrease the size of housings for electronic devices such as battery chargers and power adapters has caused heat-management challenges. In the past, heat-sinks or other thermal conductors have been used as passive heat exchangers to remove heat from a heat generating device.

### SUMMARY OF THE DISCLOSURE

For context, this section provides an overview of aspects of the disclosure and the advantages the disclosure provides. As described in further detail below, aspects of the disclosure relate to an improved housing or surface for a housing that may contain or otherwise enclose a heat dissipating device or system and/or heat generating circuit, which are terms that may be used interchangeably throughout the disclosure. In one example, the heat dissipating device may be a power converter circuit and/or a switched mode power supply circuit or circuits that dissipate heat and are contained within a housing. The outer housing containing the heat dissipating device may be contacted by a user during use and thus safety agencies and regulating bodies typically set regulations or guidelines for the maximum acceptable housing temperature. These regulations or guidelines are to prevent injury to a user, for example when plugging-in or unplugging the device. However, the maximum acceptable housing temperature set in regulations or guidelines is typically high enough to cause discomfort or negatively impact a user experience or a user's perception of the device. Heat-sinks or other thermal conductors have been used as passive heat exchangers to remove heat from a heat dissipating device. However, heat-sinks thermally conduct heat away from the source of the heat and while this is effective for regulating the temperature of an electronic device, a user may experience discomfort when contacting a product due to an increase in temperature of a housing or outer surface of the product. Aspects of the disclosure are related to a housing or a housing surface that includes grasping features that generally decrease the surface area of the housing that a user contacts during normal use (i.e., grasping or otherwise holding the housing). Decreasing or minimizing the surface area that a user contacts during use of the housing may decrease or otherwise reduce a user's perceived sensation of high surface temperature and improves the user experience and/or the user's perception of the product.

In testing aspects described herein, it was observed that the decrease in surface area contacted by a user provides a significant decrease in perceived temperature of the surface of the housing. This significant decrease in perceived temperature by a user is likely due to one of, or a combination of, the thermal break caused by the airspace between a user's skin and surfaces of the housing and a combination of physical and physiological phenomena. With respect to the physical and physiological phenomena, a typical human's skin has neurons (thermoreceptors) that include hot thermoreceptors and cold thermoreceptors. The hot thermoreceptors are most active at temperatures greater than about 45 degrees Celsius, and the cold thermoreceptors are most active at temperatures less than about 15-18 degrees Celsius. The density of hot thermoreceptors on a typical human fingertip, for example, is about 1.6 per square millimeter. Thus, by decreasing the points of contact with, for example, a human fingertip, the number of thermoreceptors activated decreases, which likely results in the decrease in perceived temperature. Thermoreceptors differ from pain receptors which are activated when a temperature rises to a level that could cause injury to a human.

In the various aspects described in detail with respect to the Figures below, a number of housings with grasping features are shown and described. In most instances the housing is shown as having a certain shape and dimensions. However, it will be appreciated by one of ordinary skill in the art that the housing and/or grasping features described herein are applicable to any housing containing a heat dissipating device with an external housing. For example, aspects of the disclosure may be added onto or integrated with the housing of mobile phones, gaming systems or controllers thereof; flashlights or lighting devices; cameras, video cameras or other imaging devices; or batteries.

The detailed examples described below show housings with grasping features integrated therewith. The grasping features may instead be added onto or otherwise connected to an otherwise relatively flat surface. For example, any grasping features that limit or reduce the contact surface area may be adhered to a surface as an appliqué, raised decal, or other adherable feature. In some aspects of the disclosure, the grasping features may be adhered to a surface using an adhesive that is either pre-applied to a bottom surface of the grasping features and/or is applied to the housing. The grasping features may also be over-molded or otherwise molded onto a housing surface. In some aspects of the disclosure, the grasping features may be multi-layered and may be applied onto a surface as multiple layers to build up the grasping features.

In one aspect of the disclosure that is usable with any of the examples described herein is an housing for a heat dissipating device. The housing may also be referred to as an enclosure. The housing may be formed using a non-metallic material like polycarbonate or similar thermoplastic. In some examples, the housing may be molded or formed as a single or unitary component or structure with the grasping features described in this disclosure integrally formed thereon. In another example, the housing may be formed of a plastic or thermoplastic with the grasping features described in this disclosure machined therein. In another example, the housing may for example be formed of a material such as aluminum, magnesium, or alloys thereof with grasping features formed of a non-metallic material such as plastic, thermoplastic, or rubbers added onto or otherwise permanently connected or adhered to the housing. Examples that are applicable to the features described in this section are described in further detail below with respect to the Figures.

This overview and the detailed description that follows have been presented for illustration and description. It is not intended to be exhaustive nor to limit the disclosure to the forms described. Numerous modifications are possible considering the teachings herein, including any combination of the different examples described herein. Some of those modifications have been discussed and others will be understood by those skilled in the art. The various aspects were chosen and described to illustrate the principles of the present disclosure and various aspects as are suited to the particular use contemplated. The scope of the present disclosure is, of course, not limited to the examples or aspects set forth herein but can be employed in any number of applications and equivalent devices by those of ordinary skill in the art. Rather, it is hereby intended the scope be defined by the claims appended hereto.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1A shows an isometric view of one example implementation of the disclosure with a user contacting the surface of a housing containing a heat dissipating device therein.

FIG. 1B is an enlarged view of a user contacting the housing surface of the example implementation of the disclosure shown in FIG. 1A.

FIG. 1C is another enlarged view of a user contacting the housing surface of the example implementation of the disclosure shown in FIGS. 1A and 1B.

FIG. 2A is an isometric view of a housing according to one example implementation of the disclosure.

FIG. 2B is an enlarged front view of a portion of the housing of FIG. 2A.

FIG. 3A is an isometric view of a housing according to one example implementation of the disclosure.

FIG. 3B is an enlarged view of a portion of the housing of FIG. 3A according to one example implementation of the disclosure.

FIG. 3C is a view of the housing of FIGS. 3A and 3B according to one example implementation of the disclosure.

FIG. 4A is an isometric view of a housing according to one example implementation of the disclosure.

FIG. 4B is an enlarged top view of a portion of the housing of FIG. 4A.

FIG. 5 is an isometric view of a housing containing a heat dissipating device and/or circuit according to one example implementation of the disclosure.

FIG. 6A is an isometric view of a housing according to one example implementation of the disclosure.

FIG. 6B is an isometric view of a housing with a portion of the outer covering removed to show features below the outer covering.

FIG. 6C is an enlarged rear view of the portion of the housing in FIGS. 6A and 6B.

FIG. 7 is an isometric view of a housing according to one example implementation of the disclosure.

FIG. 8 is an isometric view of a housing according to one example implementation of the disclosure.

FIG. 9 is an isometric view of a housing according to one example implementation of the disclosure.

FIG. 10A is an enlarged partial view of a portion of a housing according to one example implementation of the disclosure.

FIG. 10B is a further-enlarged partial view of the grasping features of FIG. 10A.

FIG. 11A is an isometric view of a housing according to one example implementation of the disclosure.

FIG. 11B is an enlarged view of the portion of the housing in FIG. 11A.

### DETAILED DESCRIPTION

### I. Terminology

Throughout the disclosure, the terms substantially or approximately may be used as a modifier for a geometric relationship between elements or for the shape of an element or component. While the terms substantially or approximately are not limited to a specific variation and may cover any variation that is understood by one of ordinary skill in the art to be an acceptable level of variation, some examples are provided as follows. In one example, the term substantially or approximately may include a variation of less than 10% of the dimension of the object or component. In another example, the term substantially or approximately may include a variation of less than 5% of the object or component. If the term substantially or approximately is used to define the angular relationship of one element to another element, one non-limiting example of the term substantially or approximately may include a variation of 5 degrees or less. These examples are not intended to be limiting and may be increased or decreased based on the understanding of acceptable limits to one of skill in the relevant art.

For disclosure purposes, directional terms are expressed with a standard frame of reference when the aspects described herein are in an in-use orientation. In some examples, the directional terms are expressed generally with relation to a left-hand coordinate system. In other examples, the directional terms may be expressed generally with relation to a right-hand coordinate system. Terminology such as top, bottom, upper, lower, left, right, above, below, vertical, lateral, are used for illustrative purposes. Terms to convey size and dimension, such as length, width, distance, thickness, etc, may be used. It should be appreciated that the orientation and arrangement may change and not functionally affect the embodiments of the present disclosure. For ease and clarity of explanation, the elements discussed herein will be referred to by the specific example orientation shown in the figures.

Terms such as a, an, and the, are not intended to refer to only a singular entity, but also include the general class of which a specific example may be used for illustration. The terms a, an, and the, may be used interchangeably with the term at least one. The phrases at least one of and comprises at least one of followed by a list refers to any one of the items in the list and any combination of two or more items in the list. All numerical ranges are inclusive of their endpoints and non-integer values between the endpoints unless otherwise stated.

The terms first, second, third, and fourth, among other numeric values, may be used in this disclosure. Unless otherwise noted, those terms are used in their relative sense only. Certain components may be present in interchangeable and/or identical multiples (e.g., pairs). For these components, the designation of first, second, third, and/or fourth may be applied to the components merely as a matter of convenience in the description.

### II. Detailed Examples

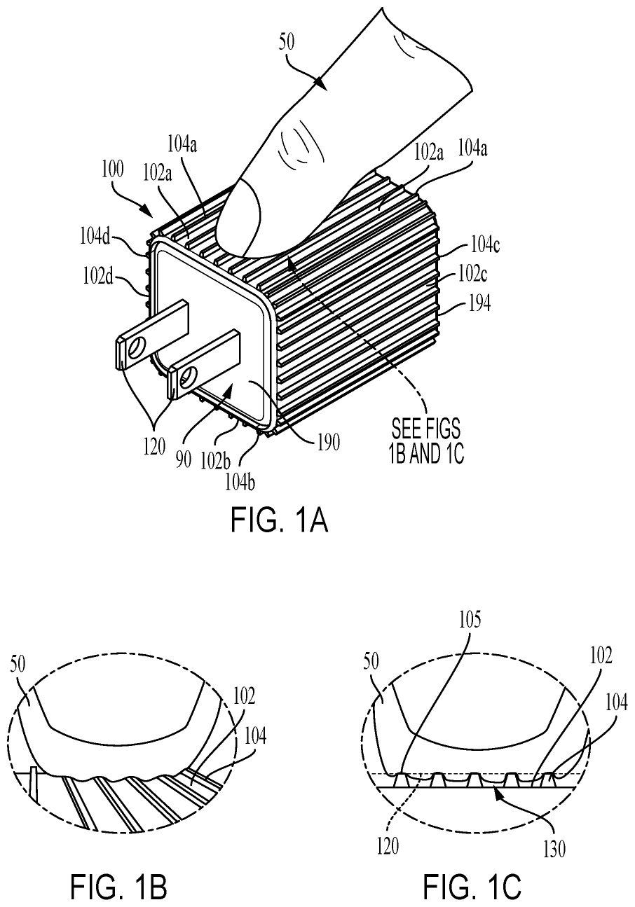

FIGS. 1A, 1B, and 1C, show one example implementation of the disclosure. A product 90 may for example have an outer housing 100. The product 90 may further include a heat dissipating device or circuit which is enclosed by the outer housing 100. The heat dissipating device may also be referred to as a heat dissipative device. Further, the outer housing 100 may also be referred to as a housing or an enclosure. Some examples of heat dissipating devices may include but are not limited to any one or a combination of a power converter circuit, an alternating current to direct current converter, a switched mode power supply circuit and/or any power supply circuit. Some examples of heat dissipating or generating circuits or devices are disclosed in U.S. patent application Ser. No. 14/261,873, titled: USB Charging with Data Communication, and filed on Apr. 25, 2014 and/or U.S. patent application Ser. No. 14/682,986, titled: Active Reduced Voltage Switching using Secondary Switch, and filed on Apr. 9, 2015, which are hereby incorporated by reference in their entirety. As shown in FIG. 1A, the surface or face 190 may for example include two prongs configured to input into a receptacle of a standard wall outlet. It is noted that while a specific prong configuration is shown (i.e., a North American, Type A, non-grounded prong configuration), any known prong configuration may be substituted. For example, the product 90 may include a ground prong (e.g., may include “Type B” prongs). Some additional examples of prongs include but are not limited to: Type C, Type D, Type E, Type F, Type G, Type H, Type I, Type J, Type K, Type L, Type M, Type N, or Type O prongs. As noted above, the prong configuration is not limited to any specific configuration and may include any known power prong configuration. In one example, the surface 190 may instead include an interface for interchangeably connecting multiple different prong modules, which may be useful to consumers that travel to areas that require different prong configurations.

The housing 100 may include a front portion 190 and a rear portion 194. In some examples, the rear portion may include a universal serial bus (USB) connector. The USB connector may for example be a USB Type A, USB Type C, USB Micro and/or USB Mini connector to name a few examples. In the examples noted above, the heat dissipating circuitry within the product 90 may for example convert alternating current received from a wall outlet or the like at the prongs 120 to direct current to be supplied to a powered or charged device via a cable plugged into the port in the rear portion 194. In some examples, the heat dissipating circuitry may include monitoring and/or regulation circuitry to monitor and/or regulate any one or combination of voltage, current, and/or temperature of the product 90 to optimize power delivery to the powered or charged device. As noted above, while some examples are provided herein, aspects described herein are usable with any type of housing to enclose a heat dissipating device or circuitry.

The housing 100 may for example include a series of grasping features 104. It is noted that throughout the disclosure, the terms grasping features, surface features, and/or regions of maximum thickness may be used interchangeably. The housing 100 may further include a housing wall portion 102. Throughout the disclosure the terms housing wall portion, housing wall portion surface, outer wall surface, and/or regions of minimum thickness may be used interchangeably.

As shown in the example in FIG. 1A, the grasping portion of housing 100 is four-sided. It should be appreciated that the housing 100 shown has six sides with four grasping or gripping sides, a front side, and a back side. The grasping sides may include grasping features, as shown and discussed. For the example shown, housing 100 includes first housing wall portion 102a, second housing wall portion 102b, third housing wall portion 102c, and a fourth housing wall portion 102d. One of the four sides may for example include a first series of grasping features 104a (only a single of the multiple grasping features is labeled to prevent obstructing of the view) that protrude from or otherwise extend from a first housing wall portion 102a. Similarly, a second of the four sides may for example include a second series of grasping features 104b (only a single of the multiple grasping features is labeled to prevent obstructing of the view) that protrude from or otherwise extend from a second housing wall portion 102b. Likewise, the housing 100 may further include a third and/or fourth side with a third series of grasping features 104c that extend from a third housing wall portion 102c and a fourth series of grasping features 104d that extend from a fourth housing wall portion 102d.

The grasping features 104 may minimize or reduce the surface area of the housing 100, which a user can easily contact or may prevent or minimize a user's contact with a wall portion 102 of the housing 100. For example, as shown in FIGS. 1A, 1B, and 1C, when a user grasps or otherwise contacts the housing 100 with their finger(s) 50, the grasping features 104 minimize the surface area of the housing 100 which the user contacts and may distance or space a user's finger or skin from the housing wall portion 102 or otherwise prevent the user's finger or skin from contacting the housing wall portion 102. One non-limiting example of this minimization or reduction of contact surface area is shown in FIG. 1C. An imaginary dotted-line segment 120 is provided to show that if a user were to grasp or otherwise contact a substantially flat wall or surface 120, the user would likely contact the wall along the entire length of the segment 120. However, if a user grasps the example housing 100 shown in FIGS. 1A, 1B and 1C with grasping features 104, the primary contact surfaces will be at the top surfaces 105 of the grasping features. Further, the protrusions of the grasping features spaces or distances a user's skin from the housing wall portion 102 and creates airspaces 130 between the user's skin and the housing wall portion 102, which may further provide a thermal break to insulate the user from heat that dissipates from or is otherwise conducted through the walls of the housing 100 to the outer surface of the housing wall portion 102. It should be noted that in other embodiments surfaces 190 and 194 could also include the grasping features such that those surfaces would also benefit from the teachings of the present disclosure. Throughout this disclosure, in subsequent figures, the surfaces equivalent to 190 and 194 are shown as flat surfaces for clarity of the figures but in each case the grasping features can be included on those surfaces such that the entire outside surface of the enclosure has grasping features.

The grasping features described in this disclosure may be different from a heatsink in that the grasping features are designed to reduce a user's perceived temperature of the housing and/or surface. Heatsinks are typically passive components designed to absorb or otherwise transfer heat from the housing and disperse heat away from the housing. Heatsinks are typically made of lower thermal impedance materials such as metals and ceramics. As such, heatsinks facilitate the removal of heat, thereby substantially reducing the temperature of the housing which the heatsink is attached. In contrast, the aspects of the present disclosure described herein may not substantially reduce the temperature of the gripping surface of the housing and/or provide an effective means of transferring heat away from the housing. Rather, the grasping features of the present disclosure alter the characteristics of the gripping surface such that the perceived temperature of the housing is reduced. In one experiment, the housing with grasping features had the same perceived temperature (i.e., did not feel warmer or hotter to a user holding the housing) while dissipating from 40% to 50% more energy than a substantially identical housing without the grasping features.

It is noted that throughout the disclosure, the reduction or minimization of user contact with the surface of the housing is referred to. One example of this reduction or minimization of user contact can be quantified via a percentage (P) of the total surface area of surfaces that are likely to be contacted by a user for the housing with grasping features 104 to a like-dimensioned housing with flat or substantially flat surfaces (e.g., a housing with walls at the periphery of the grasping features 104 as shown by dotted line 120 in FIG. 1C).

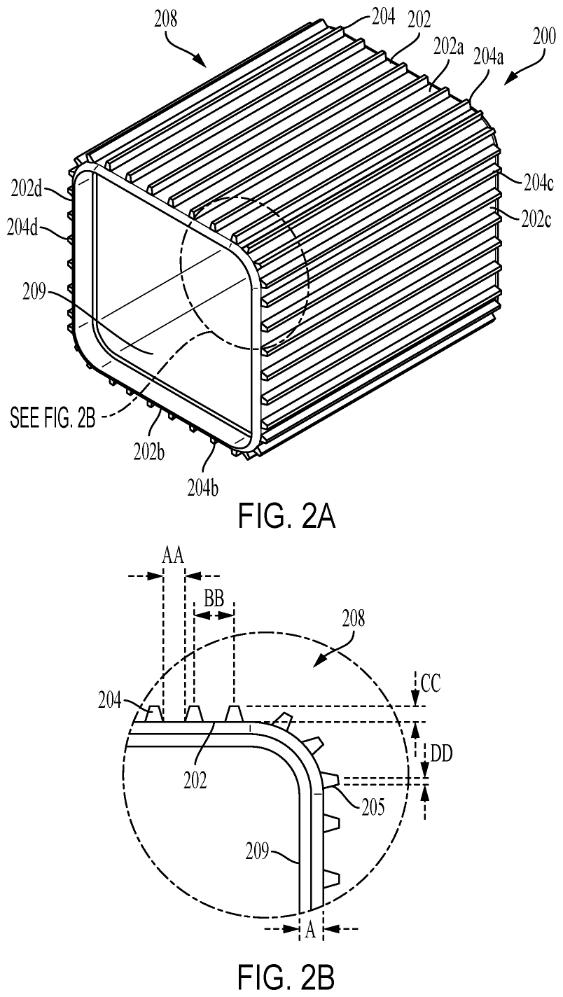

The ratio of the surfaces that are likely to be contacted for the housing with grasping features 104 to a like-dimensioned housing with flat or substantially flat surfaces may be found in the following equation, expressed as a percentage P:

$$P = \frac{{A}_{C}}{{A}_{T}} \times 100 \qquad Equation 1$$

where A_{C} is the total surface area of all the contact surfaces of the grasping features 104 (e.g., top surfaces 105 in FIG. 1C) and A_{T} is the total surface area of surfaces or planes at the periphery of the contact surfaces (e.g., along the imaginary dotted-line segment 120). In some aspects, the percentage P may be less than 33%. In another aspect, the percentage P may be between 5% and 40%. In another aspect the percentage P may be between 10% and 35%. In yet another aspect, the percentage P may be between 10% and 33%. As discussed in detail below, this reduction or minimization of user contact with the housing 100 can be accomplished in a number of ways with various grasping features, of which non-limiting examples are described with respect to FIGS. 2A, 2B, 3A, 3B, 3C, 4A, 4B, 5, 6A, 6B, 6C, 7, 8, 9, 10A, 10B, 11A, and 11B.

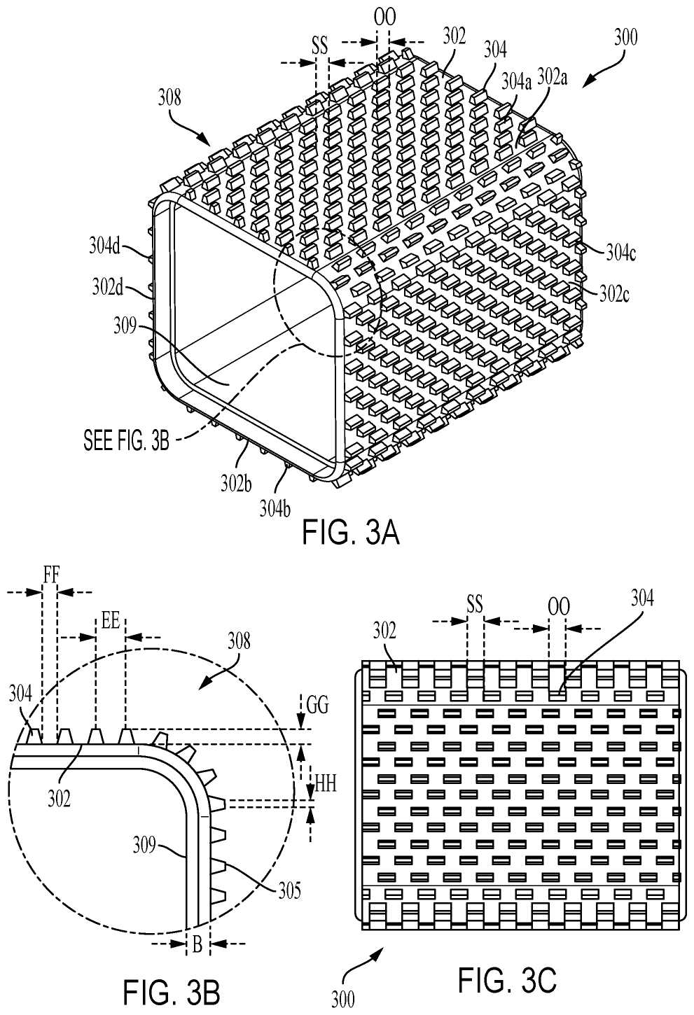

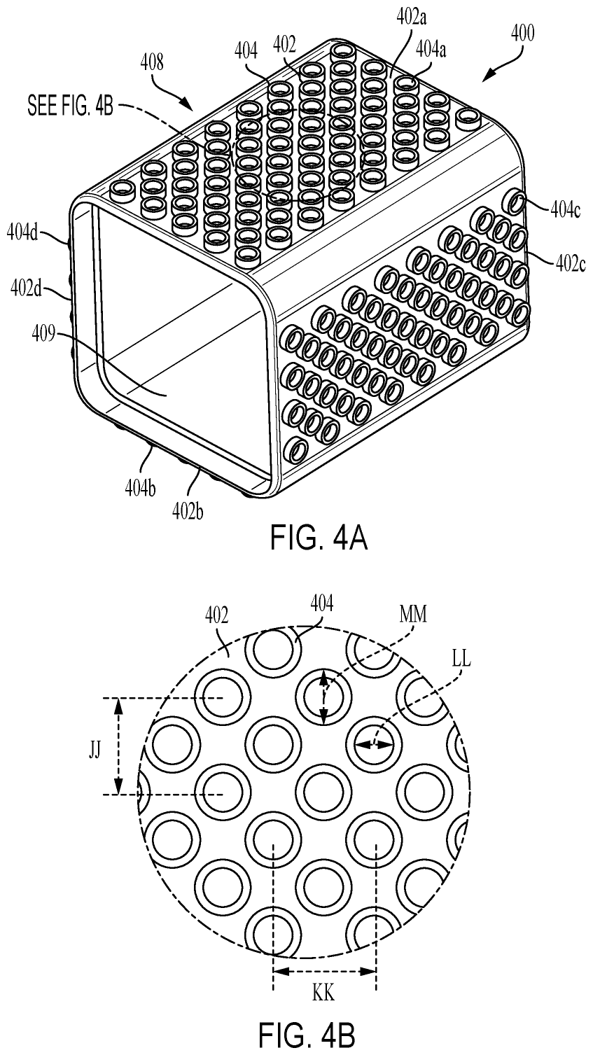

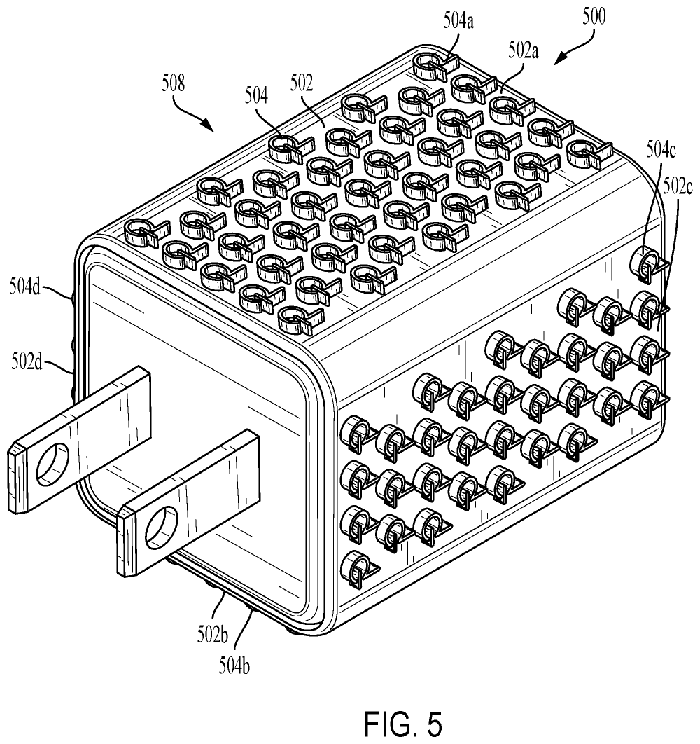

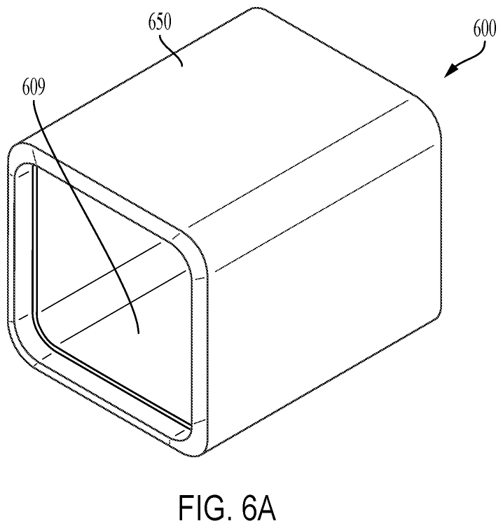

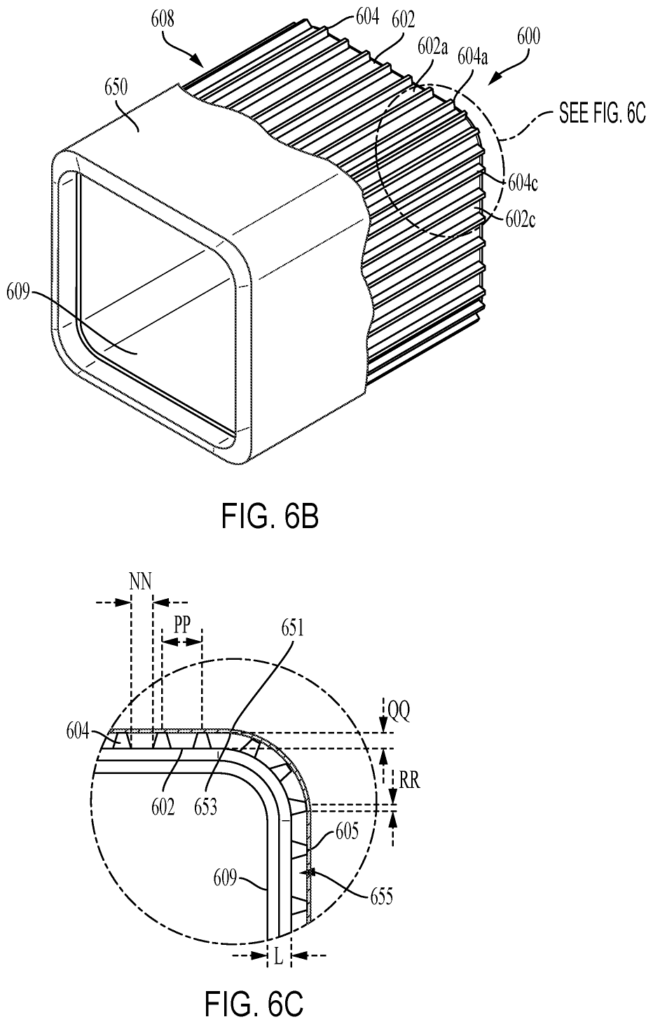

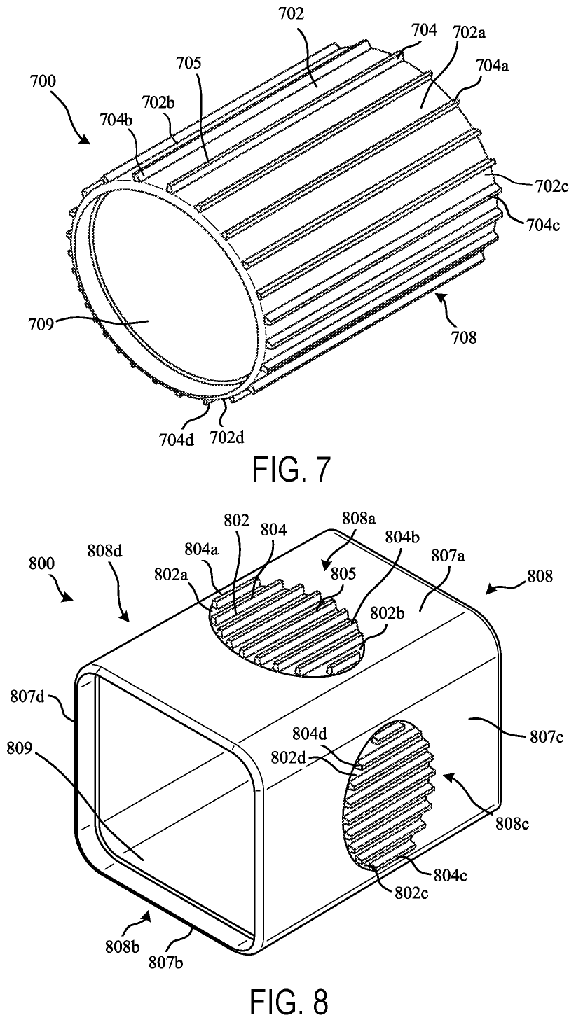

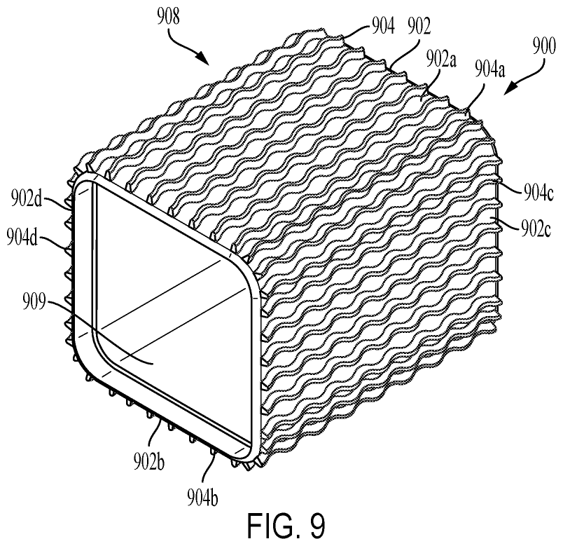

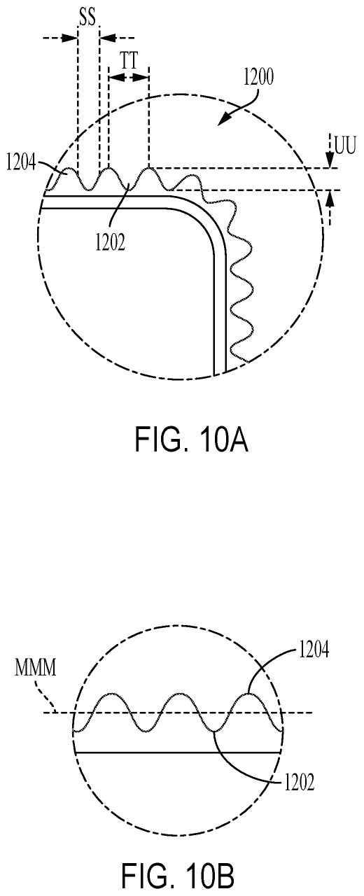

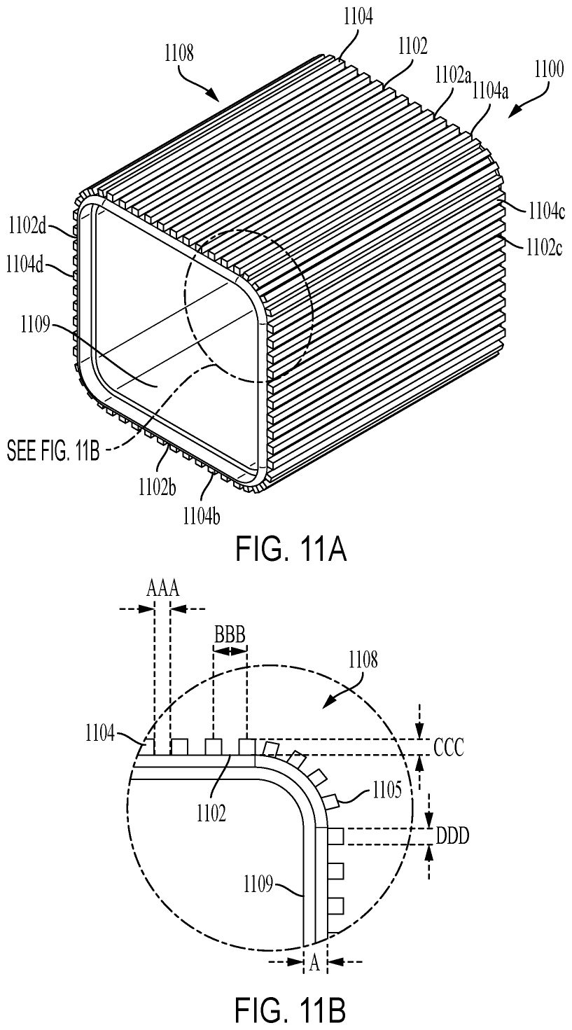

For example, FIGS. 2A and 2B show a housing 200 which may share similarities with or may be analogous with housing 100 in FIGS. 1A, 1B, and 1C, housing 300 in FIGS. 3A, 3B, and 3C, housing 400 in FIGS. 4A and 4B, housing 500 in FIG. 5, housing 600 in FIGS. 6A, 6B, and 6C, housing 700 in FIG. 7, housing 800 in FIG. 8, housing 900 in FIG. 9, housing 1200 in FIGS. 10A and 10B and/or housing 1100 in FIGS. 11A and 11B. The housing 200 may include an inner surface or wall 209 and an external surface or wall 208. The external surface or wall 208 may include a series of grasping features 204 that protrude from housing wall portion(s) 202 of the housing 200. The housing wall portions 202 and/or the grasping features 204 may form the external surface, wall, or surface 208 of the housing 200. It is noted that the terms housing wall portion and housing wall portion surface may be used interchangeably throughout this disclosure. In the example of FIGS. 1A, 1B, 1C, 2A, and 2B, the grasping features 204 may for example be elongated rails or protrusions that protrude from the housing wall portion(s) 202. For the example shown, the grasping features 204 are shown as a continuous protrusion from the front portion to the back portion of the housing 200.

As shown in the example in FIG. 2A, the grasping portion of the housing 200 is four-sided. It should be appreciated that the housing 200 shown has six sides with four grasping or gripping sides, a front side, and a back side. The grasping sides may include grasping features, as shown and discussed. For the example shown, housing 200 includes a first housing wall portion 202a, second housing wall portion 202b, third housing wall portion 202c and fourth housing wall portion 202d. One of the four sides may for example include a first series of grasping features 204a (only a single of the multiple grasping features is labeled to prevent obstructing of the view) that protrude from or otherwise extend from a first housing wall portion 202a. Similarly, a second of the four sides may for example include a second series of grasping features 204b (only a single of the multiple grasping features is labeled to prevent obstructing of the view) that protrude from or otherwise extend from a second housing wall portion 202b. In one example, the first housing wall portion 202a, the second housing wall portion 202b, the first plurality of grasping features 204a, and the second plurality of grasping features 204b may be formed as a single, unitary structure. Likewise, the housing 200 may further include a third and/or fourth side with a third series of grasping features 204c that extend from a third housing wall portion 202c and a fourth series of grasping features 204d that extend from a fourth housing wall portion 202d. The housing wall portions 202 and respective grasping features 204 may form a unitary structure for the housing 200. It should be appreciated that the housing may have more or fewer sides than the housing 200 shown. Further, the grasping features 204 may form channels or concavities between adjacent grasping features in one direction. In one example, the housing 200 may have one or more channels or concavities between each of the adjacent grasping features 204. In one example, the grasping features 204 shown in FIG. 2A may be referred to as ridges. It should be appreciated that the grasping features 204 may be referred to as regions of maximum thickness while the channel or concavities between grasping features 204 may be referred to as regions of minimum thickness.

It is noted that while the reference numbers associated with the first series of grasping features 204a, second series of grasping features 204b, third series of grasping features 204c, and fourth series of grasping features 204d are each shown on different sides of the housing 200, the location and/or associated side of each grasping feature or series of grasping features is provided as an example only and is not intended to be limiting. For example, the first series of grasping features 204a and second series of grasping features 204b may be on the same wall or side of the housing 200 instead of on opposite sides as shown in FIG. 2B. Similarly, it is noted that while the reference numbers associated with the first housing wall portion 204a, second housing wall portion 204b, third housing wall portion 204c, and fourth housing wall portion 204d are each shown on different sides of the housing 200, the location and/or associated side of each housing wall portion is provided as an example only and is not intended to be limiting. For example, the first housing wall portion 204a and second housing wall portion 204b may be on the same wall or side of the housing 200 instead of on opposite sides as shown in FIG. 2B.

The housing wall minimum thickness or distance between the inner surface or wall 209 and the housing wall portion 202 shown by reference A in FIG. 2B may be from 0.75 to 4.0 millimeters (mm). In one example, the housing wall minimum thickness may be a thickness required for mechanical integrity and may be partially dependent on the material chosen for the housing. In another example, the distance A may be from 1.0 to 2.0 mm. In one example the distance A may be approximately 1.5 mm.

In FIG. 2B, the spacing between a first grasping feature and a second grasping feature of the grasping features is labeled as AA. In one example, the distance AA may be from 0.75 to 2.0 mm. In one example, the distance AA may be approximately 1.0 mm.

The spacing between the center-point of a first and second grasping feature of the grasping features 204 is labeled BB in FIG. 2B. In one example, the distance BB may be from 0.75 to 4.0 mm. In one example, the distance BB may be approximately 2.0 mm.

FIG. 2B additionally shows a height of one or more of the grasping features 204 as height CC. In one example, the height CC may be from 0.75 to 2.0 mm. In one example, the height CC may be approximately 1.0 mm. It should be appreciated that as the height CC increases, the distance AA may also increase. In one example, the distance AA is substantially equal to the height CC.

The width of the topmost surface or contact surface 205 of one or more of the grasping features 204 is labeled as DD in FIG. 2B. In one example, the width DD may be from 0.5 to 2.0 mm. In one example, the width DD may be approximately 0.75 mm. The width of the topmost surface may be referred to interchangeably throughout the specification as the top surface minor dimension.

As shown in FIG. 2A, in one example, the housing 200 may have thirty-eight (38) grasping features 204 (that are substantially evenly spaced to form a repetitive pattern. While in the example above, thirty-eight grasping features are shown (i.e., approximately nine-and-one-half grasping features on each of the first, second, third, and fourth housing wall portions 202a, 202b, 202c, and 202d), any one of or all of the first, second, third, and fourth housing wall portions 202a, 202b, 202c, and 202d may include any number from five to two-hundred grasping features. It should be appreciated that the dimensions of the grasping features 204 may be selected such that they prevent a finger from touching the surface at the base of the grasping feature 204 under a gripping force sufficient to perform the desired operation, while preventing the contact surface from cutting or otherwise causing injury to a user's skin. A number of example alternative grasping features are described below with respect to FIGS. 3A, 3B, 3C, 4A, 4B, 5, 6A, 6B, 6C, 7, 8, 9, 10A, 10B, 11A, and 11B. Further, it is noted that while a six sided housing (with four grasping sides) is shown in FIGS. 1A, 1B, 1C, 2A, and 2B, housings 100 and/or 200 may instead have a curved, oval, and/or round cross section as shown in FIG. 7 for example.

FIGS. 3A, 3B, and 3C show a housing 300 which may share similarities with or may be analogous with housing 100 in FIGS. 1A-1C, housing 200 in FIGS. 2A and 2B, housing 400 in FIGS. 4A and 4B, housing 500 in FIG. 5, housing 600 in FIGS. 6A, 6B, and 6C, housing 700 in FIG. 7, housing 800 in FIG. 8, housing 900 in FIG. 9, housing 1200 in FIGS. 10A and 10B and/or housing 1100 in FIGS. 11A and 11B. The housing 300 may include an inner surface or wall 309 and an external surface or wall 308. The external surface or wall 308 may include a series of grasping features 304 that protrude from housing wall portion(s) 302 of the housing 300. The housing wall portions 302 and/or the grasping features may for example form the external surface or wall 308 of the housing 300. The housing wall portions 302 and/or the grasping features 304 may form the external surface, wall, or surface 308 of the housing 300 and the terms housing wall portion and housing wall portion surface may be used interchangeably. The grasping features 304 may for example be segmented protrusions that protrude from the housing wall portion(s) 302. For the examples shown in FIGS. 3A, 3B, and 3C, the grasping features 304 may be segments of a rail or segments of an elongated protrusion of grasping features 104 (FIGS. 1A-1C) or grasping features 204 (FIGS. 2A-2B). Further, the grasping features 304 may form channels or concavities between adjacent grasping features in two directions. In one example, the housing 300 may have one or more channels or concavities between each of the adjacent grasping features. For the example shown, the grasping features may be referred to as pillars.

As shown in the example in FIG. 3A, the grasping portion of housing 300 is four-sided. It should be appreciated that the housing 300 shown has six sides with four grasping or gripping sides, a front side, and a back side. The grasping sides may include grasping features, as shown and discussed. For the example shown, housing 300 includes the first housing wall portion 302a, second housing wall portion 302b, third housing wall portion 302c and fourth housing wall portion 302d. One of the four sides may include a first series of grasping features 304a (only a single of the multiple grasping features is labeled to prevent obstructing of the view) that protrude from or otherwise extend from a first housing wall portion 302a. Similarly, a second of the four sides may include a second series of grasping features 304b (only a single of the multiple grasping features is labeled to prevent obstructing of the view) that protrude from or otherwise extend from a second housing wall portion 302b. Likewise, the housing 300 may further include a third and/or fourth side with a third series of grasping features 304c that extend from a third housing wall portion 302c and a fourth series of grasping features 304d that extend from a fourth housing wall portion 302d. The housing wall portions and 302 and respective grasping features 304 may form a unitary structure for the housing 300. It should be appreciated that the housing may have more or fewer sides than the housing 300 shown. It should be appreciated that the grasping features 304 may be referred to as regions of maximum thickness while the concavities between grasping features 304 may be referred to as regions of minimum thickness.

Similar to above, it is noted that while the reference numbers associated with the series of grasping features and wall portions are shown on different sides of the housing 300, the location and/or associated side of the series of grasping features or wall portions is provided as an example only and is not intended to be limiting. For example, the first series of grasping features 304a and second series of grasping features 304b may be on the same wall or side of the housing 300 instead of on opposite sides as shown in FIG. 3A. Similarly, the first housing wall portion 304a and second housing wall portion 304b may be on the same wall or side of the housing 300 instead of on opposite sides as shown in FIG. 3A.

The housing wall minimum thickness or distance between the inner surface or wall 309 and the housing wall portion 302 shown by reference B in FIG. 3B may be from 0.75 to 4.0 millimeters (mm). In another example, the thickness B may be from 1.0 to 2.0 mm. In one example the thickness B may be approximately 1.5 mm.

In FIG. 3B, the spacing between a first grasping feature and a second grasping feature of the grasping features 304 is labeled as FF. In one example, the distance FF may be from 0.75 to 2.0 mm. In one example, the distance FF may be approximately 1.0 mm.

The spacing between the center-point of a first and second grasping feature of the grasping features 304 is labeled EE in FIG. 3B. In one example, the distance EE may be from 0.75 to 4.0 mm. In one example, the distance EE may be approximately 2.0 mm.

FIG. 3B additionally shows a height of one or more of the grasping features 304 as height GG. In one example, the height GG may be from 0.75 to 2.0 mm. In one example, the height GG may be approximately 1.0 mm. As the height GG increases, the distance FF may also increase. In one example, the distance FF is substantially equal to the height GG.

The width of the topmost surface or contact surface 305 of one or more of the grasping features 304 is labeled as HH in FIG. 3B. In one example, the width HH may be from 0.5 to 2.0 mm. In one example, the width HH may be approximately 0.75 mm. The width of the topmost surface may be referred to interchangeably throughout the specification as the top surface minor dimension.

FIGS. 3A and 3C show a distance SS from one grasping feature to another grasping feature and a length OO of a grasping feature 304. In one example, the distance SS may be from 0.75 to 2.0 mm. In one example, the distance SS may be approximately 1.0 mm. In one example, the length OO may be from 1.0 to 5.0 mm. It should be appreciated that if the length of OO spanned the entire length of the housing 300, the embodiment shown in FIG. 3A would be similar to the embodiment shown in FIG. 2A. The length OO may be less than the length of housing 300. The length of the housing 300 may refer to the distance between the front side and the back side of housing 300. The height of housing 300 may refer to the distance between the top and bottom of the housing 300 while the width may refer to the distance between the remaining sides.

As shown in FIG. 3A, the housing 300 may have approximately six-hundred (600) grasping features 304 (that are substantially evenly spaced to form a repetitive pattern. While in the example above, approximately six-hundred grasping features are shown (i.e., approximately one-hundred-and-fifty grasping features on each of the first, second, third, and fourth housing wall portions 302a, 302b, 302c, and 302d), any one of or all of the first, second, third, and fourth housing wall portions 302a, 302b, 302c, and 302d may include any number from five (5) to two-hundred (200) grasping features. It is noted that the aforementioned grasping features may be interchanged with or combined with any of the grasping features described in this disclosure. In addition, the grasping features may instead be arranged in a non-repetitive or non-symmetrical pattern or randomized. It should be appreciated that the dimensions of the grasping features 304 may be selected such that they prevent a finger from touching the surface at the base of the grasping feature 304 under a gripping force sufficient to perform the desired operation, while preventing the contact surface from cutting or otherwise damaging a user's skin. It should be appreciated that the longest dimension of the grasping features 304 shown in FIG. 3A is substantially parallel with the longest dimension of the housing 300. However, it should be appreciated that the longest dimension of the grasping features may not be aligned with the longest dimension of the housing 300. For example, the longest dimension of the grasping features 304 may be substantially perpendicular to the longest dimension of the housing 300. In another example, the longest dimension of the grasping features 304 may rotated by any angle from the longest dimension of the housing 300. Further, the longest dimension of the grasping features 304 may rotate to form a chevron pattern or a random arrangement.

FIGS. 4A and 4B show a housing 400 which may share similarities with or may be analogous with housing 100 in FIGS. 1A, 1B, and 1C, housing 200 in FIGS. 2A and 2B, housing 300 in FIGS. 3A, 3B, and 3C, housing 500 in FIG. 5, housing 600 in FIGS. 6A, 6B, and 6C, housing 700 in FIG. 7, housing 800 in FIG. 8, housing 900 in FIG. 9, housing 1200 in FIGS. 10A and 10B and/or housing 1100 in FIGS. 11A and 11B. The housing 400 may include an inner surface or wall 409 and an external surface or wall 408. The external surface or wall 408 includes a series of grasping features 404 that protrude from housing wall portion(s) 402 of the housing 400. The grasping features 404 may be circular or concentric-circular protrusions that protrude from the housing wall portion(s) 402.

The housing 400 shown has six sides with four grasping or gripping sides, a front side, and a back side. The grasping sides may include grasping features, as shown and discussed. For the example shown, housing 400 includes the first housing wall portion 402a, second housing wall portion 402b, third housing wall portion 402c, and fourth housing wall portion 402d. Each of these wall portions include a series of grasping features, shown as the first 404a, second 404b, third 404c, and fourth 404d grasping features, respectively, which protrude from or otherwise extend from their respective wall portion. The housing wall portions 402 and respective grasping features 404 may form a unitary structure for the housing 400. In one example, the housing 400 may have one or more concavities between each of the adjacent grasping features 404 and/or within the center of each of the grasping features 404. While the series of grasping features and associated wall portions are shown on different sides of the housing 400, these features and wall portions may be on the same side of housing 400 or a combination of same or different sides of housing 400.

While not specifically shown in FIG. 4A or 4B, the housing wall minimum thickness or distance between the inner surface or wall 409 and the housing wall portion 402 (e.g., a distance shown by reference B in FIG. 3B) may be from 0.75 to 4.0 millimeters (mm). In another example, the distance from the inner surface or wall 409 to the outer surface of the housing wall portion 402 may be from 1.0 to 2.0 mm. In one example the distance from the inner surface or wall 409 to the housing wall portion 402 may be approximately 1.5 mm.

In FIG. 4B, the spacing between a center of a first grasping feature and a second grasping feature of the grasping features 404 along a first direction is labeled as JJ. In one example, the distance JJ may be from 3.0 to 7.0 mm.

The spacing between a center of a first grasping feature and a second grasping feature of the grasping features 404 along a second direction is labeled as KK. In one example, the distance KK may be from 3.0 to 7.0 mm.

The inner diameter of each of the grasping features 404 is labeled LL in FIG. 4B. In one example, the diameter LL may be from 0.75 to 2.0 mm.

The outer diameter of each of the grasping features 404 is labeled MM in FIG. 4B. In one example, the diameter MM may be from 2.0 to 3.0 mm longer than the inner diameter LL. In another example, the diameter MM may be from 1.0 to 5.0 mm.

As shown in FIG. 4A, in one example, the housing 400 may have approximately two-hundred-and-seventy-two (272) grasping features 404 that are substantially evenly spaced to form a repetitive pattern. While in the example above, approximately two-hundred-and-seventy-two grasping features 404 are shown (i.e., approximately sixty-eight grasping features on each of the first, second, third, and fourth housing wall portions 402a, 402b, 402c, and 402d), any one of or all of the first, second, third, and fourth housing wall portions 402a, 402b, 402c, and 402d may include any number from five (5) to two-hundred (200) grasping features. It is noted that the aforementioned grasping features may be interchanged with or combined with any of the grasping features described in this disclosure. In addition, the grasping features may instead be arranged in a non-repetitive or non-symmetrical pattern.

FIG. 5 shows a housing 500, which may share similarities with or may be analogous with housing 100 in FIGS. 1A, 1B, and 1C, housing 200 in FIGS. 2A and 2B, housing 300 in FIGS. 3A, 3B, and 3C, housing 400 in FIGS. 4A and 4B, housing 600 in FIGS. 6A, 6B, and 6C, housing 700 in FIG. 7, Housing 800 in FIG. 8, housing 900 in FIG. 9, housing 1200 in FIGS. 10A and 10B and/or housing 1100 in FIGS. 11A and 11B. The housing 500 may include an inner surface or wall (hidden from view-see reference 409 in FIGS. 4A and 4B) and an external surface or wall 508. The external surface or wall 508 includes a series of grasping features 504 that protrude from housing wall portion(s) 502 of the housing 500. The grasping features 504 may for example be extended protrusions shaped as a design or logo as shown. In some examples, the logo may be a company logo or other source identifier. The housing wall portions 502 and/or the grasping features 504 may form the external surface, wall, or surface 508 of the housing 500 and the term housing wall portion and housing wall portion surface may be used interchangeably throughout the disclosure.

The housing 500 shown has six sides with four grasping or gripping sides, a front side, and a back side. The grasping sides may include grasping features, as shown and discussed. For the example shown, housing 500 may include a first housing wall portion 502a, a second housing wall portion 502b, a third housing wall portion 502c, and a fourth housing wall portion 502d. Each of these wall portions include a series of grasping features, shown a first 504a, second 504b, third 504c and fourth 504d series of grasping features, respectively, which protrude from or otherwise extend from their respective wall portions. The housing wall portions 502 and respective grasping features 504 may form a unitary structure for the housing 500. The housing 500 may have one or more concavities between each of the adjacent grasping features 504 and/or within each of the grasping features 504.

The series of grasping features 504 and wall portions 502 are each shown on different sides of the housing 500, however, they may be on the same side or a combination of same or different sides of housing 500.

While not specifically shown in FIG. 5, the housing wall minimum thickness or distance between the inner surface or wall 509 (hidden from view-see reference 409 in FIGS. 4A and 4B) and the housing wall portion outer surface 502 (e.g., a distance shown by reference B in FIG. 3B) may be from 0.75 to 4.0 millimeters (mm). In another example, the distance from the inner surface or wall to the housing wall portion 502 may be from 1.0 to 2.0 mm. In one example, the distance from the inner surface or wall to the housing wall portion 502 may be approximately 1.5 mm.

As shown in FIG. 5, in one example, the housing 500 may have approximately one-hundred-and-sixty-four (164) grasping features 504 (that are substantially evenly spaced to form a repetitive pattern. While in the example above, approximately one-hundred-and-sixty-four grasping features 504 are shown (i.e., approximately forty-one (41) grasping features on each of the first, second, third, and fourth housing wall portions 502a, 502b, 502c, and 502d), any one of or all of the first, second, third, and fourth housing wall portions 502a, 502b, 502c, and 502d may include any number from five (5) to two-hundred (200) grasping features. It is noted that the aforementioned grasping features may be interchanged with or combined with any of the grasping features described in this disclosure.

FIGS. 6A, 6B, and 6C show examples of a housing 600 that may share similarities with or may be analogous with housing 100 in FIGS. 1A, 1B, and 1C, housing 200 in FIGS. 2A and 2B, housing 300 in FIGS. 3A, 3B, and 3C, housing 400 in FIGS. 4A and 4B, housing 500 in FIG. 5, housing 700 in FIG. 7, housing 800 in FIG. 8, housing 900 in FIG. 9, housing 1200 in FIGS. 10A and 10B and/or housing 1100 in FIGS. 11A and 11B. The example shown in FIGS. 6A, 6B, and 6C may have an outer film, layer, or covering 650 covering one or more grasping features 604 (FIGS. 6B and 6C). It is noted that while the grasping features 604 shown in FIGS. 6B and 6C are similar in appearance to the grasping features 104 in FIGS. 1A, 1B, and 1C and grasping features 204 in FIGS. 2A and 2B, the aspects described herein are usable with any type of grasping features. For example, the outer film, layer, or covering 650 described in further detail below may be added to the housings shown in the other Figures of this disclosure or housing with any combination of grasping features described.

As shown in FIGS. 6B and 6C, the housing may have an inner surface or wall 609 and an external surface or wall 608. The external surface or wall 608 (shown in FIG. 6B), which may include a number of housing wall portions 602 and grasping features 604, which may be covered or partially covered with the outer film, layer, or covering 650. Throughout the disclosure the terms outer film, layer, or covering may be used interchangeably. The outer layer 650 may for example have an outer surface 651 and an inner surface 653. The thickness (i.e., a measurement from the outer surface 651 to an inner surface 653) of the outer layer 650 may for example be from 0.5 to 4.0 mm. In one example, the thickness may be approximately 0.75 mm

In some examples, the outer layer 650 may for example be a heat-shrink film or member that may be placed over the housing 600 and caused to contract or otherwise shrink over the grasping features 604 and/or external walls of the housing 600. In another example, the outer layer 650 may be molded onto or wrapped and sealed around the housing 600. The outer layer 650 may for example be formed of any one or a combination of a polyolefin, polyvinylidene fluoride, polyvinyl chloride, and/or polytetrafluoroethylene or equivalents thereof. In some examples, the outer layer 650 may be formed as a separate component and slid over or otherwise connected, adhered, melted to, and/or ultrasonically welded to the housing 600 via the grasping features 604. In the aforementioned example, the outer layer 650 may be formed of any known plastic which includes but is not limited to any one or combination of known acrylics, polyesters, silicones, and polyurethanes. In some examples, the outer layer 650 may be transparent or semi-transparent to allow the grasping feature 604 and/or the wall portions 602 to be seen therethrough, which may for example be preferably when the grasping features are in the form of designs or logos (e.g., as shown and described with respect to FIG. 5). In some aspects of the disclosure, the outer layer 650 may instead be opaque or semi-opaque to hide or otherwise conceal the grasping features 604 and/or the wall portions 602 thereunder. In some examples, the outer layer 650 may be multi-layered and/or may be a composite or substrate.

As shown in FIGS. 6A and 6B, the outer layer 650 may for example completely cover the series of grasping features 604 that protrude from the housing wall portion(s) 602 of the housing. It is noted that while FIG. 6A shows the outer layer completely covering the grasping features 604 and housing wall portion(s) 602, the outer layer may instead only partially cover any one of or both of the housing wall portion(s) 602 and/or the grasping features 604 so that parts thereof are exposed.

The external surface or wall 608 of the housing 600 may include a series of grasping features 604 that protrude from housing wall portion(s) 602 of the housing 600. The housing wall portions 602 and/or the grasping features 604 may form the external surface, wall, or surface 608 of the housing 600 and the term housing wall portion and housing wall portion surface may be used interchangeably throughout this disclosure. The grasping features 604 may for example be elongated rails or protrusions that protrude from the housing wall portion(s) 602. In the example shown, the grasping features 604 are shown as a continuous protrusion from the front portion to the back portion of the housing 600.

As shown in the example in FIGS. 6A and 6B, the housing 600 shown has six sides with four grasping or gripping sides, a front side, and a back side. The grasping sides may include grasping features, as shown and discussed. In the example shown, the housing 600 includes a first housing wall portion 602a, second housing wall portion (hidden from view), third housing wall portion 602c and fourth housing wall portion (hidden from view). One of the four sides may for example include a first series of grasping features 604a (only a single of the multiple grasping features is labeled to prevent obstructing of the view) that protrude from or otherwise extend from a first housing wall portion 602a. Similarly, a second of the four sides may for example include a second series of grasping features (hidden from view) that protrude from or otherwise extend from a second housing wall portion. Likewise, the housing 600 may further include a third and/or fourth side with a third series of grasping features 604c that extend from a third housing wall portion 602c and a fourth series of grasping features (hidden from view) that extend from a fourth housing wall portion. The housing wall portions 602 and respective grasping features 604 may form a unitary structure for the housing 600. It should be appreciated that the housing may have more or fewer sides than the housing 600 shown. Further, the grasping features 604 may form channel or concavities between adjacent grasping features in one direction. In one example, the housing 600 may have one or more channels or concavities between each of the adjacent grasping features 604.

While the first series of grasping features 604a, second series of grasping features, third series of grasping features 604c, and fourth series of grasping features are each shown or may be implied as being located on different sides of the housing 600, the location and/or associated side of each grasping feature may be on the same side or a combination of same and different sides.

As noted above, the housing 600 may further include an outer layer 650 either partially or completely covering the grasping features 604 and/or the housing wall portion(s) 602. The outer layer 650 may for example be supported by or have an inner surface 653 in contact with or adjacent to contact surfaces or top surfaces 605 (FIG. 6C) of each one of the grasping features 604. As shown in FIG. 6C, the outer layer 650 may contact only or substantially only the contact surfaces or top surfaces 605 of each grasping feature causing airspaces or openings 655 bounded by or otherwise defined by one or more grasping features 604 and the wall portion 602 therebetween and the inner surface 653 of the outer layer 650. Accordingly, the outer layer 650 effectively spans across the grasping features 604 and thus when a user grasps the outer surface 651 of the outer layer 650, a user's skin is spaced or distanced from the wall portion(s) 602 therebelow. Thus, the combination of the grasping features 604 and the outer layer 650 effectively reduces the surface area of the housing portions that a user's skin comes into contact with or that a user's skin comes into proximity of, which similarly to the aspects described above, may prevent dissipation of heat to a user's skin and thus reduces a user's perception or sensation of heat dissipating from the housing 600. Further, the openings 655 may further provide a thermal break to insulate the user from heat that dissipates from or is otherwise conducted through the walls of the housing to the outer surface 651 of the outer layer 650.

As shown in FIG. 6C, the housing wall minimum thickness or distance between the inner surface or wall 609 and the housing wall portion 602 shown by reference L in FIG. 6C may be from 0.75 to 4.0 millimeters (mm). In yet another example, the thickness L may be from 1.0 to 2.0 mm. In one example the thickness L may be approximately 1.5 mm.

In FIG. 6C, the spacing between a first grasping feature and a second grasping feature of the grasping features is labeled as NN. In one example, the distance NN may be from 0.75 to 2.0 mm. In one example, the distance NN may be approximately 1.0 mm.

The spacing between the center-point of a first and second grasping feature of the grasping features 604 is labeled PP in FIG. 6C. In one example, the distance PP may be from 0.75 to 4.0 mm. In one example, the distance PP may be approximately 2.0 mm.

FIG. 6C additionally shows a height of one or more of the grasping features 604 as height QQ. In one example, the height QQ may be from 0.75 to 2.0 mm. In one example, the height QQ may be approximately 1.0 mm.

The width of the topmost surface or contact surface 605 (i.e., the surface that contacts inner surface 653 of the outer layer 650) of one or more of the grasping features 604 is labeled as RR in FIG. 6C. In one example, the width RR may be from 0.5 to 2.0 mm. In one example, the width RR may be approximately 0.75 mm. The width of the topmost surface may be referred to interchangeably throughout the specification as the top surface minor dimension.

As shown in FIG. 6B, in one example, the housing 600 may have thirty-eight (38) grasping features 604 (that are substantially evenly spaced to form a repetitive pattern. While in the example above, thirty-eight grasping features are shown (i.e., approximately nine-and-a-half grasping features on each of the first, second, third, and fourth housing wall portions), any one of or all of the first, second, third, and fourth housing wall portions may include any number from five to two-hundred grasping features. A number of example alternative grasping features are described with respect to FIGS. 7, 8, 9, 10A, 10B, 11A, and 11B. Further, it is noted that while six sided housing (with four grasping sides) is shown in FIGS. 6A, 6B, and 6C, housing 600 may instead have a curved, oval, and/or round cross section as shown in FIG. 7 for example.

FIG. 7 shows an example of a housing 700 that may share similarities with or may be analogous with housing 100 in FIGS. 1A, 1B, and 1C, housing 200 in FIGS. 2A and 2B, housing 300 in FIGS. 3A, 3B, and 3C, housing 400 in FIGS. 4A and 4B, housing 500 in FIG. 5, housing 600 in FIGS. 6A, 6B, and 6C, housing 700 in FIG. 7, housing 800 in FIG. 8, housing 9 in FIG. 9, housing 1200 in FIGS. 10A and 10B and/or housing 1100 in FIGS. 11A and 11B. The example shown in FIG. 7 may have a curved, circular, or oval housing for all portion(s) 704 with grasping features 702. is noted that while the grasping features 704 shown in FIG. 7 are similar in appearance to the grasping features 104 in FIGS. 1A, 1B, and 1C and grasping features 204 in FIGS. 2A and 2B, the aspects described herein are usable with any type of grasping feature. For example, the curved, circular or oval housing 700 detailed below may include the grasping features 304 shown in FIGS. 3A, 3B, and 3C, grasping features 404 shown in FIGS. 4A and 4B and/or grasping features 504 shown in FIG. 5 either as an alternative to grasping features 702 and/or in combination thereof. Further, the grasping features may have a film, layer, or covering (e.g., outer layer 650 in FIG. 6A-6C) as described above. It should be appreciated that the film, layer or covering for the housing 700 would have a shape similar to housing 700.

As shown in FIG. 7, the housing 700 may have an inner surface or wall 709 and an external surface or wall 708. The external surface or wall 708, may include a plurality of housing wall portions 702 and grasping features 704. For example, the housing wall portions 702 and/or the grasping features 704 may form the external surface, wall, or surface 708 of the housing 700 and the term housing wall portion and housing wall portion surface may be used interchangeably throughout this disclosure. The grasping features 704 may for example be elongated rails or protrusions that protrude from the housing wall portion(s) 702. In the example shown, the grasping features 704 are shown as a continuous protrusion from the front portion to the back portion of the housing 700. Instead of a four-sided housing as described in the aspects above, the housing 700 may instead have curved walls as shown. The curved housing includes a plurality of housing wall portions 702a, 702b, 702c, and 702d. It should be appreciated that the plurality of housing wall portions 702a, 702b, 702c, and 702d are shown for illustrative purposes, however there may be more or less wall portions.

The external surface or wall 708 may include a plurality of grasping features 704a, 704b, 704c, and 704d that protrude from or otherwise extend from their respective plurality of housing portions 702a, 702b, 702c, and 702d. In one example, the number of grasping features 704 are selected to create airspace between a user's fingers and the outer wall 708 of housing 700. The plurality of housing wall portions 702a, 702b, 702c, and 702d and respective grasping features 704 may form a unitary structure for the housing 700. The grasping features 704 may form channel or concavities between adjacent grasping features in one direction. In one example, the housing 700 may have one or more channels or concavities between each of the adjacent grasping features 704.

It is noted that while the reference numbers associated with the plurality of grasping features 704a, 704b, 704c, and 704d, along with the plurality of wall portions 702a, 702b, 702c, and 702d are each shown or may be implied as being located at a specific location on housing 700, the location is provided as an example only and is not intended to be limiting.

The housing wall minimum thickness or distance between the inner surface or wall 709 and the housing wall portion 702 (e.g., shown by reference L in FIG. 6C may be from 0.75 to 4.0 millimeters (mm)). In yet another example, the minimum wall thickness may be from 1.0 to 2.0 mm. In one example the minimum wall thickness may be approximately 1.5 mm.

The spacing between a first grasping feature and a second grasping feature of the grasping features (e.g., labeled as NN in FIG. 6C) may be from 0.75 to 2.0 mm. In one example, the spacing may be approximately 1.0 mm.

The spacing between the center-point of a first and second grasping feature of the grasping features 704 (e.g., labeled PP in FIG. 6C) may be from 0.75 to 4.0 mm. In one example, the spacing may be approximately 2.0 mm.

The height of one or more of the grasping features 704 (e.g., height QQ in FIG. 6C) may be from 0.75 to 2.0 mm. In one example, the height may be approximately 1.0 mm. It should be appreciated that as the height QQ increases, the distance NN may also increase. In one example, the distance NN is substantially equal to the height QQ.

The width of the topmost surface or contact surface 705 (e.g., labeled as RR in FIG. 6C) may be from 0.5 to 2.0 mm. In one example, the width may be approximately 0.75 mm. The width of the topmost surface may be referred to interchangeably throughout the specification as the top surface minor dimension.

As shown in FIG. 7, in one example, the housing 700 may have twenty-six (26) grasping features 704 (that are substantially evenly spaced to form a repetitive pattern. While in the example above, twenty-six grasping features are shown, however, the housing may include any number from five to two-hundred grasping features. Further, the grasping features do not need to be evenly spaced. A number of example alternative grasping features are described with respect to FIGS. 8, 9, 10A, 10B, 11A, and 11B.

FIG. 8 shows an example housing 800 that may share similarities with or may be analogous with housing 100 in FIGS. 1A, 1B, and 1C, housing 200 in FIGS. 2A and 2B, housing 300 in FIGS. 3A, 3B, and 3C, housing 400 in FIGS. 4A and 4B, housing 500 in FIG. 5, housing 600 in FIGS. 6A, 6B, and 6C, housing 700 in FIG. 7, housing 800 in FIG. 8, housing 900 in FIG. 9, housing 1200 in FIGS. 10A and 10B and/or housing 1100 in FIGS. 11A and 11B.

As shown in FIG. 8, the housing 800 may have an inner surface or wall 809 and an external surface or wall 808, which may include four or more housing sides for example. The external surface or wall 808 (shown in FIG. 6B), may include a number of housing wall portions (e.g., 802a, 802b, 802c, and/or 802d) and grasping features (e.g., 804a, 804b, 804c and/or 804d) in grasping regions 808a, 808b, 808c and/or 808d. Grasping regions 808a, 808b, 808c, and 808d are shown as oval in shape, however it should be appreciated that other grasping regions may have other shapes. It is noted that grasping regions 808b and 808d are hidden from view in FIG. 8—the grasping regions 804b and/or 804d may share similarities with or may be identical to either one of or both of grasping regions 808a and 808c shown in FIG. 8. Further, grasping regions may be omitted from any one of the sides of the housing 808. For example, grasping regions 808c and 808d may be omitted, and grasping regions 808a and 808b may be the only grasping regions on the housing 800.

In one example, each one of the housing sides may have a first region 807a, 807b, 807c, and/or 807d that are smooth or otherwise free of grasping features except in the grasping region(s) (e.g., grasping regions 808a, 808b, 808c, and/or 808d).

Each one of the grasping regions 808a, 808b, 808c, and/or 808d may include grasping features 804 that protrude from housing wall portion(s) 802 of the housing 800. The housing wall portions 802 and/or the grasping features 804 may form the external surface, wall, or surface 808 of the housing 800 and the term housing wall portion and housing wall portion surface may be used interchangeably throughout this disclosure. The grasping features 804 may for example be elongated rails or protrusions that protrude from the housing wall portion(s) 802. In the example shown, the grasping features 804 are shown as a continuous protrusion from the front portion to the back portion of each of the grasping regions 808a, 808b, 808c, and/or 808d of the housing 800.

As shown in the example in FIG. 8, the grasping portion of housing 800 is four-sided. It should be appreciated that the housing 800 shown has six sides with four grasping or gripping sections, a front side, and a back side. The grasping sides may include grasping features, as shown and discussed. Any one of or all of the grasping regions 808a, 808b, 808c, and/or 808d may include a first housing wall portion 802a, second housing wall portion 802b, third housing wall portion 802c, and fourth housing wall portion 802d. It is noted that while only a single of the multiple grasping features is labeled to prevent obstructing of the view, any number of grasping portions may be included any one of or combination of the grasping regions 808a, 808b, 808c, and/or 808d, and may protrude from or otherwise extend from a first housing wall portion 802a, second housing wall portion 802b, third housing wall portion 802c, and/or fourth housing wall portion 802d. As noted above, while two grasping regions 808a and 808c are shown, the housing may further include grasping regions 808b and/or 808d, which are hidden from view in FIG. 8. Grasping regions 808b and/or 808d may be identical to or similar to grasping regions 808a and/or 808c and likewise may have similar or identical grasping portions and/or housing wall portion(s) as described with respect to grasping regions 808a and/or 808c. Further, the grasping features 804 may form channel or concavities between adjacent grasping features in one direction. In one example, the housing 800 may have one or more channels or concavities between each of the adjacent grasping features 804.

The housing wall minimum thickness or distance between the inner surface or wall 809 and the housing wall portion 802 (e.g., shown by reference L in FIG. 6C may be from 0.75 to 4.0 millimeters (mm)). In yet another example, the minimum wall thickness may be from 1.0 to 2.0 mm. In one example the minimum wall thickness may be approximately 1.5 mm.

The spacing between the first grasping feature and the second grasping feature of the grasping features (e.g., labeled as NN in FIG. 6C) may be from 0.75 to 2.0 mm. In one example, the spacing may be approximately 1.0 mm.

The spacing between the center-point of a first and second grasping feature of the grasping features 804 (e.g., labeled PP in FIG. 6C) may be from 0.75 to 4.0 mm. In one example, the spacing may be approximately 2.0 mm.

The height of one or more of the grasping features 804 (e.g., height QQ in FIG. 6C), may be from 0.75 to 2.0 mm. In one example, the height may be approximately 1.0 mm. It should be appreciated that as the height QQ increases, the distance NN may also increase. In one example, the distance NN is substantially equal to the height QQ.

The width of the topmost surface or contact surface 805 (e.g., labeled as RR in FIG. 6C) may be from 0.5 to 2.0 mm, one example, the width may be approximately 0.75 mm. The width of the topmost surface may be referred to interchangeably throughout the specification as the top surface minor dimension.

As shown in FIG. 8, in one example, each of the grasping regions 808 may have nine (9) grasping features 804 that are evenly spaced to form a repetitive pattern. However, it should be appreciated that the grasping features 804 may not be evenly spaced. While in the example above, nine grasping features are shown in each of the grasping regions 808, any one or more of the grasping regions may include any number from three (3) to eighty (80) grasping features. Several examples of alternative grasping features are described with respect to FIGS. 9, 10A, 10B, 11A, and 11B. Further, it is noted that while six sided housing (with four grasping sides) is shown in FIGS. 8, housing 800 may instead have a curved, oval, and/or round cross section as shown in FIG. 7 for example.

FIG. 9 shows a housing 900 that may share similarities with or may be analogous with housing 100 in FIGS. 1A, 1B, and 1C, housing 200 in FIGS. 2A and 2B, housing 300 in FIGS. 3A, 3B, and 3C, housing 400 in FIGS. 4A and 4B, housing 500 in FIG. 5, housing 600 in FIGS. 6A, 6B, and 6C, housing 700 in FIG. 7, housing 800 in FIG. 8, housing 1200 in FIGS. 10A and 10B and/or housing 1100 in FIGS. 11A and 11B. The external surface or wall 908 may include a series of grasping features 904 that protrude from housing wall portion(s) 902 of the housing 900. The housing wall portions 902 and/or the grasping features 904 may form the external surface, wall, or surface 908 of the housing 900 and the term housing wall portion and housing wall portion surface may be used interchangeably. The grasping features 904 may protrude from the housing wall portion(s) 902.

The grasping features 904 in FIG. 9 are formed as elongated protrusions that curve as they extend along the length of the protrusion. In some examples, the grasping features 904 may be elongated protrusions that form gaussian curves or sinusoidal curves. In some examples, the elongated protrusions may form transverse Gaussian or sinusoidal curves or a transverse Gaussian or sinusoidal wave. The grasping features 904 may also form channels or concavities between adjacent grasping features in two directions. In one example, the housing 900 may have one or more channels or concavities between each of the adjacent grasping features. For the example shown, the grasping features may be referred to as curved channels.

As shown in the example in FIG. 9, the housing 900 shown has six sides with four grasping or gripping sides, a front side, and a back side. The grasping sides may include grasping features, as shown and discussed. For the example shown in FIG. 9, the housing 900 includes the first housing wall portion 902a, second housing wall portion 902b, third housing wall portion 902c and fourth housing wall portion 902d. One of the four sides may include a first series of grasping features 904a (only a single of the multiple grasping features is labeled to prevent obstructing of the view) that protrude from or otherwise extend from a first housing wall portion 902a. The other of the four sides may include a second series of grasping features 904b, third series 904c, and/or fourth series 904d which extend from their respective second 902b, third 902c and/or fourth 902d housing wall portion. The housing wall portions 902 and respective grasping features 904 may form a unitary structure for the housing 900. It should be appreciated that the housing may have more or fewer sides than the housing 900 shown. It should be appreciated that the grasping features 904 may be referred to as regions of maximum thickness while the concavities between grasping features 904 may be referred to as regions of minimum thickness.

It is noted that while the first series of grasping features 904a, second series of grasping features 904b, third series of grasping features 904c, and fourth series of grasping features 904d are each shown on different sides of the housing 900, the location of these grasping features may be on the same or a combination of same or different sides of housing 900.

While not intended to be limiting, examples of dimensions of the housing wall minimum thickness or distance between the inner surface or wall 909 and the housing wall portion 902 are described above with reference to dimension A, reference B in FIG. 3B, reference and/or reference L in FIG. 6C.

Further it is noted that while the cross-section of each grasping portion is shown as a trapezoid in FIG. 9, the cross-section may instead be identical to or share features with, including the example dimensional ranges, described with respect to FIG. 2B, FIG. 3B, FIG. 6C, and/or FIGS. 10A and 10B.

As shown in FIG. 9, the housing 900 may have approximately thirty-eight (38) grasping features 304 (that are evenly spaced to form a repetitive pattern. While in the example above, thirty-eight grasping features are shown, any one of or all the first, second, third, and fourth housing wall portions 902a, 902b, 902c, and 902d may include number from five (5) to two-hundred (200) grasping features. It is noted that the grasping features may be interchanged with or combined with any of the grasping features described in this disclosure. In addition, the grasping features may instead be arranged in a non-repetitive or non-symmetrical pattern. It should be appreciated that the dimensions of the grasping features 904 may be selected such that they prevent a finger from touching the surface at the base of the grasping feature 904 under a gripping force sufficient to perform the desired operation, while preventing the contact surface from cutting or otherwise damaging a user's skin.

FIGS. 10A and 10B show a portion of an example housing 1200 and cross section(s) of grasping features 1204. The shown alternative grasping features 1204 of FIG. 10A and FIG. 10B are applicable to and may be implemented as an alternative to any one of or all of the grasping features 104 in FIG. 1A-1C, 204 in FIGS. 2A and 2B, 304 in FIGS. 3A, 3B, and 3C, 404 in FIGS. 4A and 4B, 504 in FIG. 5, 604 in FIGS. 6B and 6C, 704 in FIG. 7, 804 in FIG. 8, 904 in FIGS. 9, and/or 1104 in FIGS. 11A and 11B. The cross section of the grasping features 1204 may form a sinusoidal curve or wave.

The grasping features 1204 and wall portions 1202 therebetween may also form channels or concavities between adjacent grasping features in two directions. In one example, the housing 1200 may have one or more channels or concavities between each of the adjacent grasping features.

Further it is noted that while the cross-section of each grasping portion is shown as a curved surface or series of curves in FIGS. 10A and 10B, the cross-section may instead be identical to or share features with, including the example dimensional ranges, described with respect to FIG. 2B, FIG. 3B, FIG. 6C, and/or FIGS. 11A and 11B.

In one example implementation, a distance SS from an intersection of the midline MMM (FIG. 10B) of a first grasping feature to the intersection of the midline of a second adjacent grasping feature may be from 0.75 to 2.0 mm. In one example, the distance SS may be approximately 1.0 mm.

In one example implementation, a distance TT from a peak of a first grasping feature to a peak of a second adjacent grasping feature may be from 0.75 to 4.0 mm. In one example, the distance TT may be approximately 2.0 mm.

In one example implementation, a height or amplitude UU of any one of or each grasping feature 1204 may be from 0.75 to 2.0 mm. In one example, the height or amplitude UU may be approximately 1.0 mm. It should be appreciated that the greater the height or amplitude UU, the greater the distance SS. In one example, the distance SS is equal to amplitude UU.

FIG. 11A and FIG. 11B shows a housing 1100 that may share similarities with or may be analogous with housing 100 in FIGS. 1A, 1B, and 1C, housing 200 in FIGS. 2A and 2B, housing 300 in FIGS. 3A, 3B, and 3C, housing 400 in FIGS. 4A and 4B, housing 500 in FIG. 5, housing 600 in FIGS. 6A, 6B, and 6C, housing 700 in FIG. 7, housing 800 in FIG. 8, and/or housing 900 in FIG. 9. The external surface or wall 1108 may include a series of grasping features 1104 that protrude from housing wall portion(s) 1102 of the housing 1100. The housing wall portions 1102 and/or the grasping features 1104 may form the external surface, wall, or surface 1108 of the housing 1100 and the term housing wall portion and housing wall portion surface may be used interchangeably. The grasping features 1104 may protrude from the housing wall portion(s) 1102. The grasping features 1104 in FIGS. 11A and 11B are formed as elongated protrusions that have a square or rectangular cross-section. In some examples, the grasping features 1104 may be elongated protrusions with a square or rectangular cross-section. In one example, the housing 1100 may have one or more channels or concavities between each of the adjacent grasping features.

As shown in the example in FIG. 11A, the housing 1100 shown has six sides with four grasping or gripping sides, a front side, and a back side. The grasping sides may include grasping features, as shown and discussed. For the example shown in FIG. 11A, the housing 1100 includes the first housing wall portion 1102a, second housing wall portion 1102b, third housing wall portion 1102c and fourth housing wall portion 1102d. One of the four sides may include a first series of grasping features 1104a (only a single of the multiple grasping features is labeled to prevent obstructing of the view) that protrude from or otherwise extend from a first housing wall portion 1102a. Similarly, other sides may include a second series of grasping features 1104b a third series of grasping features 1104c and a fourth series of grasping features 1104d that extend from their respective housing wall portion 1102b, 1102c, and 1102d. The housing wall portions 1102 and respective grasping features 1104 may form a unitary structure for the housing 1100. It should be appreciated that the housing may have more or fewer sides than the housing 1100 shown. It should be appreciated that the grasping features 1104 may be referred to as regions of maximum thickness while the concavities between grasping features 1104 may be referred to as regions of minimum thickness.

It is noted that while the first series of grasping features 1104a, second series of grasping features 1104b, third series of grasping features 1104c, and fourth series of grasping features 1104d and their respective housing wall portions are each shown on different sides of the housing 1100, however, the grasping features and housing wall portions may be on the same or combination of same and different sides of housing 1100.

The housing wall minimum thickness or distance between the inner surface or wall 1109 and the housing wall portion 1102 shown by reference A in FIG. 11B may be from 0.75 to 4.0 millimeters (mm). In one example, the housing wall minimum thickness may be a thickness required for mechanical integrity and may be partially dependent on the material chosen for the housing. In yet another example, the distance A may be from 1.0 to 2.0 mm. In one example the distance A may be approximately 1.5 mm.

In FIG. 11B, the spacing between a first grasping feature and a second grasping feature of the grasping features is labeled as AAA. In one example, the distance AAA may be from 0.75 to 2.0 mm. In one example, the distance AAA may be approximately 1.5 mm.

The spacing between the center-point of a first and second grasping feature of the grasping features 1104 is labeled BBB in FIG. 11B. In one example, the distance BBB may be from 0.75 to 4.0 mm. In one example, the distance BBB may be approximately 2.0 mm.

FIG. 11B additionally shows a height of one or more of the grasping features 1104 as height CCC. In one example, the height CCC may be from 0.75 to 2.0 mm. In one example, the height CCC may be approximately 1.0 mm. It should be appreciated that if the height CCC increases, the distance AAA may also increase. In one example, the distance AAA is substantially equal to the height CCC.

The width of the topmost surface or contact surface 1105 of one or more of the grasping features 1104 is labeled as DDD in FIG. 11B. In one example, the width DDD may be from 0.75 to 2.0 mm. In one example, the width DDD may be approximately 1.0 mm. The width DDD of the topmost surface may be referred to interchangeably throughout the specification as the top surface minor dimension. The cross-section of the grasping feature 1104 is shown as substantially rectangular or square in shape.

As shown in FIG. 11A, in one example, the housing 1100 may have fifty-eight (35) grasping features 1104 (that are substantially evenly spaced to form a repetitive pattern. While in the example above, fifty-eight grasping features are shown any one of or all of the first, second, third, and fourth housing wall portions 1102a, 1102b, 1102c, and 1102d may include any number from five to two-hundred grasping features. It should be appreciated that the dimensions of the grasping features 1104 may be selected such that they prevent a finger from touching the surface at the base of the grasping feature 1104 under a gripping force sufficient to perform the desired operation, while preventing the contact surface from cutting or otherwise causing injury to a user's skin.

The detailed description set forth above in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known components are hidden from view to avoid obscuring such concepts.

Reference throughout this specification to “one embodiment”, “an embodiment”, “one example” or “an example” means that a particular feature, structure or characteristic described in connection with the embodiment or example is included in at least one embodiment of the present invention. Thus, appearances of the phrases “in one embodiment”, “in an embodiment”, “one example” or “an example” in various places throughout this specification are not necessarily all referring to the same embodiment or example. Furthermore, the particular features, structures or characteristics may be combined in any suitable combinations and/or subcombinations in one or more embodiments or examples. In addition, it is appreciated that the figures provided herewith are for explanation purposes to persons ordinarily skilled in the art and that the drawings are not necessarily drawn to scale.

This written description uses examples to disclose aspects of the invention, including the preferred embodiments, and also to enable any person skilled in the art to practice the aspects thereof, including making and using any devices or systems and performing any incorporated methods. The patentable scope of these aspects is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims. Aspects from the various embodiments described, as well as other known equivalents for each such aspect, can be mixed and matched by one of ordinary skill in the art to construct additional embodiments and techniques in accordance with principles of this application.

What is claimed is:

1. A housing for containing at least one heat dissipating device, the housing configured to be grasped or otherwise held by a user, the housing comprising:
a first housing wall portion with a first plurality of grasping features that protrude from the first housing wall portion; and
a second housing wall portion with a second plurality of grasping features that protrude from the second housing wall portion, wherein the first plurality of grasping features and second plurality of grasping features prevent the user from contacting the first housing wall portion and the second housing wall portion.

2. The housing of claim 1, wherein the first plurality of grasping features are protrusions, or the first housing wall portion comprises a plurality of concavities between the first plurality of grasping features, or the first plurality of grasping features are protrusions and the first housing wall portion comprises a plurality of concavities between the first plurality of grasping features.

3. The housing of claim 2, wherein the second plurality of grasping features are protrusions, or the second housing wall portion comprises a plurality of concavities between the second plurality of grasping features, or the second plurality of grasping features are protrusions and the second housing wall portion comprises a plurality of concavities between the second plurality of grasping features.

4. The housing of claim 3, wherein the first plurality of grasping features and the second plurality of grasping features are formed of a non-metallic material.

5. The housing of claim 4, wherein the first housing wall portion and the second housing wall portion are formed of a non-metallic material.

6. The housing of claim 5, wherein the first housing wall portion, the second housing wall portion, the first plurality of grasping features, and the second plurality of grasping features are a unitary structure.

7. The housing of claim 6, further comprising a third housing wall portion and a fourth housing wall portion, wherein the first housing wall portion and the second housing wall portion are substantially perpendicular to the third housing wall portion and the fourth housing wall portion, and wherein the first housing wall portion and the second housing wall portion are substantially parallel.

8. The housing of claim 7, wherein the third housing wall portion comprises a third plurality of grasping features that protrude from the third housing wall portion and the fourth housing wall portion comprises a fourth plurality of grasping features that protrude from the fourth housing wall portion.

9. The housing of claim 8, wherein the first housing wall portion, second housing wall portion, third housing wall portion and fourth housing wall portion form a substantially rectangular enclosure for containing the at least one heat dissipating device.

10. The housing of claim 9, wherein the first plurality of grasping features, the second plurality of grasping features, the third plurality of grasping features, and the fourth plurality of grasping features are substantially identical.

11. The housing of claim 1, wherein the at least one heat dissipating device is one or more components of a power converter contained within the housing.

12. The housing of claim 1, wherein the first plurality of grasping features is comprised of 5 to 200 grasping features and wherein the second plurality of grasping features consists of 5-200 grasping features.

13. The housing of claim 1, wherein the first plurality of grasping features and the second plurality of grasping features form a substantially repetitive pattern on the first housing wall portion and the second housing wall portion.

14. The housing of claim 1, wherein the first plurality of grasping features form a randomized or non-repetitive pattern on the first housing wall portion.

15. The housing of claim 14, wherein the second plurality of grasping features form a randomized or non-repetitive pattern on the second housing wall portion.

16. A heat dissipating circuit and a housing containing the heat dissipating circuit, the housing comprising:
a first housing wall portion with a first wall inner surface and a first wall outer surface, the first wall outer surface comprising a plurality of first grasping features extending therefrom; and
a second housing wall portion with a second wall inner surface and a second wall outer surface, the second wall outer surface having a plurality of second grasping features extending therefrom, wherein the plurality of first grasping features and plurality of second grasping features prevent a user that grasps the housing from contacting the first wall outer surface and the second wall outer surface.

17. The heat dissipating circuit and housing of claim 16, the housing further comprising:
a third housing wall portion comprising a third wall inner surface and a third wall outer surface, wherein the third wall outer surface comprises a plurality of third grasping features extending therefrom; and
a fourth housing wall portion comprising a fourth wall inner surface and a fourth wall outer surface, wherein the fourth wall outer surface comprises a plurality of fourth grasping features extending therefrom, wherein the first wall inner surface and the second wall inner surface are substantially perpendicular to the third wall inner surface and the fourth wall inner surface, and wherein the first wall inner surface and the second wall inner surface are substantially parallel.

18. The housing of claim 17, wherein the plurality of first grasping features, plurality of second grasping features, plurality of third grasping features, and plurality of fourth grasping features form a substantially repetitive pattern on the first wall outer surface, the second wall outer surface, the third wall outer surface, and the fourth wall outer surface.

19. The housing of claim 17, further comprising:
a fifth housing wall portion comprising a fourth wall inner surface and a fourth wall outer surface, wherein the fifth wall outer surface comprises a plurality of fifth grasping features extending therefrom; and
a sixth housing wall portion comprising a sixth wall inner surface and a sixth wall outer surface, wherein the sixth wall outer surface comprises a plurality of fourth grasping features extending therefrom, wherein the fifth wall inner surface and the sixth wall inner surface are substantially perpendicular to the first wall inner surface, the second wall inner surface, the third wall inner surface and the fourth wall inner surface.

20. The heat dissipating circuit and housing of claim 17, wherein the first grasping features, second grasping features, third grasping features, and fourth grasping features are formed of a non-metallic material.

21. The heat dissipating circuit and housing of claim 20, wherein the plurality of first grasping features, plurality of second grasping features, plurality of third grasping features, and plurality of fourth grasping features are substantially identical.

22. The heat dissipating circuit and housing of claim 21, wherein each of the first grasping features comprises a first grasping surface at an end thereof, each of the second grasping features comprises a second grasping surface at an end thereof, each of the third grasping features comprises a third grasping surface at an end thereof, and each of the fourth grasping features comprises a fourth grasping surface at an end thereof, wherein the first grasping surface, second grasping surface, fourth grasping surface and fourth grasping surface have a minor dimension from 0.75 millimeters (mm) to 2.0 mm.

23. The heat dissipating circuit and housing of claim 17, wherein the heat dissipating circuit is a power converter circuit.

24. A heat dissipating circuit and a housing containing the heat dissipating circuit, the housing comprising:
a first housing wall portion with a first wall inner surface and a first wall outer surface, the first wall outer surface comprising a plurality of first grasping features extending therefrom; and
a second housing wall portion with a second wall inner surface and a second wall outer surface, the second wall outer surface having a plurality of second grasping features extending therefrom, wherein the plurality of first grasping features and plurality of second grasping features distance a user's skin from first wall outer surface and the second wall outer surface when a user grasps the housing.

25. The heat dissipating circuit and housing of claim 24, wherein the housing further comprises an outer layer over the plurality of first grasping features and second grasping features, wherein the outer layer contacts a first grasping feature surface of the first grasping features and a second grasping feature surface of the second grasping features and is spaced-apart from the first wall outer surface and the second wall outer surface.

26. An enclosure containing a dissipating device, the enclosure comprising:
an enclosure wall at a periphery of the enclosure, the enclosure wall having a minimum and maximum thickness, the maximum thickness existing for a percentage of the periphery of the enclosure in at least one sectional plane of the enclosure, wherein said percentage is less than 33%, wherein a difference in the minimum and maximum wall thickness is in the range from 0.75 millimeters (mm) to 4.0 mm and wherein a minimum distance between points having a maximum wall thickness is less than 350% of the difference between the minimum and maximum wall thickness.

27. The enclosure of claim 26, wherein regions of maximum and minimum thickness form a substantially repetitive pattern around the periphery of the enclosure in at least one sectional plane of the enclosure.

28. The enclosure of claim 26, wherein one or more of the maximum thickness percentages of the periphery of the enclosure, the difference in the minimum and maximum wall thickness and the minimum distance between points having a maximum wall thickness are variable around the periphery of the enclosure in at least one sectional plane of the enclosure.

29. The enclosure of claim 26, wherein regions having substantially the maximum wall thickness form substantially continuous ridges on the periphery of the enclosure, the ridges separated by grooves, and wherein at least a portion of the grooves define the minimum wall thickness.

30. The enclosure of claim 26, wherein the dissipating device is a power converter circuit.

31. The enclosure of claim 26, wherein the dissipating device is a switched mode power supply circuit.
